(19) United States
(12) Patent Application Publication
(10) Pub. No.: US 2024/0332094 A1
(43) Pub. Date: Oct. 3, 2024

(54) METHOD AND SYSTEM FOR COMPENSATING MANUFACTURING ERROR IN SEMICONDUCTOR PROCESS

(71) Applicant: Prosemi Co., Ltd., Tainan City (TW)

(72) Inventor: Wen-Shian CHEN, Kaohsiung City (TW)

(21) Appl. No.: 18/620,287

(22) Filed: Mar. 28, 2024

(30) Foreign Application Priority Data
Mar. 29, 2023 (TW) 112112061

(51) Int. Cl. H01L 21/66; H01L 21/67; H01L 21/68

(52) U.S. Cl. CPC H01L 22/20; H01L 21/67092; H01L 21/67098; H01L 21/67248; H01L 21/681

(57) ABSTRACT

A method for compensating a manufacturing error in a semiconductor process is implemented using a system that includes at least one temperature controller. The method includes: generating a reading signal associated with a location of an alignment symbol on a substrate; generating a difference signal based on the reading signal, the difference signal indicating a difference between the location of the alignment symbol and a location of a reference alignment symbol, the reference alignment symbol being on another substrate; and generating a temperature controlling signal based on the difference signal, the temperature controlling signal controlling operation of the temperature controller to control one of a temperature of an affecting part of the substrate, a temperature of an affecting part of the another substrate, and a combination thereof. Then, a lamination process is implemented to bond the substrate and the another substrate together.

### CROSS-REFERENCE TO RELATED APPLICATION

This application claims priority to Taiwanese Invention patent application Ser. No. 112112061, filed on Mar. 29, 2023, and incorporated by reference herein in its entirety.

### FIELD

The disclosure relates to a method and a system for compensating a manufacturing error in a semiconductor process, and more particularly to a method and a system for compensating a manufacturing error using temperature control.

### BACKGROUND

As the field of semiconductor fabrication progresses, the structure of semiconductor devices have become progressively more complicated, multi-layered, and dense. During the manufacturing of semiconductor devices (in which a plurality of layers, each having a specific pattern, are laid in order), lithography is typically used to transfer one or more two-dimensional patterns onto a layer (e.g., a substrate), so as to form a patterned layer. As the patterns become smaller in scale and higher in density, more patterned layers are employed in forming a semiconductor device. When one of the layers is misaligned with a previous one of the layers, one or more layers that are to be formed after the misaligned layer may be adversely affected, which may cause the resultant semiconductor device to have malfunctions occurring within adjacent patterned layers, such as connection failures and/or short circuits. Accordingly, overlay control, which involves the control of layer-to-layer alignment of semiconductor devices, has become an important issue.

### SUMMARY

Therefore, one object of the disclosure is to provide a method for overlay control in a semiconductor process using temperature control.

According to one embodiment of the disclosure, the method for compensating a manufacturing error in a semiconductor process is implemented using a system that includes at least one temperature controller. The method includes:
generating a reading signal associated with a location of an alignment symbol on a substrate;
generating a difference signal based on the reading signal, the difference signal indicating a difference between the location of the alignment symbol and a location of a reference alignment symbol that corresponds with the alignment symbol, the reference alignment symbol being on another substrate;
generating a temperature controlling signal based on the difference signal, the temperature controlling signal controlling operation of the temperature controller in order to control one of a temperature of an affecting part of the substrate, a temperature of an affecting part of the another substrate and a combination thereof; and
after controlling the one of a temperature of an affecting part of the substrate, a temperature of an affecting part of the another substrate and a combination thereof, performing a lamination process to bond the substrate and the another substrate together.

Another one object of the disclosure is to provide a system for overlay control in a semiconductor process that is configured to implement the above-mentioned method.

According to one embodiment of the disclosure, the system is for compensating a manufacturing error in a semiconductor process, the system including:
a reading unit that generates a reading signal associated with an alignment symbol formed on a substrate;
an error calculating unit that, in response to receipt of the reading signal, determines a difference between a location of the alignment symbol and a location of a reference alignment symbol formed on another substrate, and generates a difference signal based on the reading signal, the difference signal indicating the difference;
a temperature controlling unit that, in response to receipt of the difference signal, generates at least one temperature controlling signal based on the difference signal, the temperature controlling signal controlling one of a temperature of an affecting part of the substrate, a temperature of an affecting part of the another substrate and a combination thereof; and
a lamination unit that is configured to, after controlling the one of a temperature of an affecting part of the substrate, a temperature of an affecting part of the another substrate and a combination thereof, perform a lamination process to bond the substrate and the another substrate together.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a system for compensating a manufacturing error in a semiconductor process according to one embodiment of the disclosure.

FIG. 2 illustrates an exemplary substrate according to one embodiment of the disclosure.

FIG. 3 is a flow chart illustrating steps of a method for compensating a manufacturing error using temperature control according to one embodiment of the disclosure.

FIG. 4 is a fragmentary schematic view illustrating a system for overlay control in a semiconductor process according to one embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

Throughout the disclosure, the term “coupled to” or “connected to” may refer to a direct connection among a plurality of electrical apparatus/devices/equipment via an electrically conductive material (e.g., an electrical wire), or an indirect connection between two electrical apparatus/devices/equipment via another one or more apparatus/devices/equipment, or wireless communication.

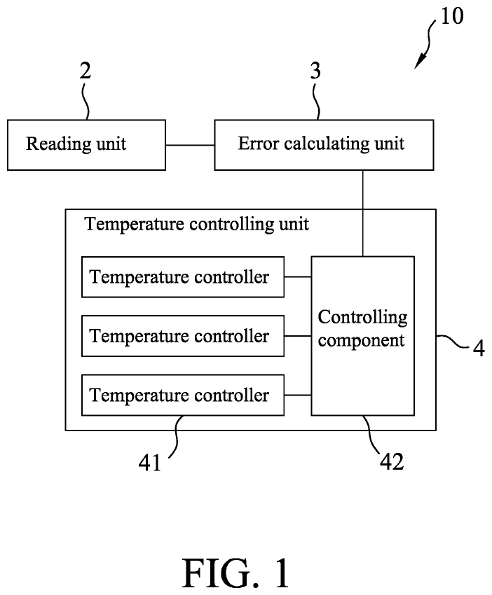

FIG. 1 is a block diagram illustrating a system 10 for compensating a manufacturing error in a semiconductor process according to one embodiment of the disclosure. In embodiments, the system 10 includes a reading unit 2, an error calculating unit 3, and a temperature controlling unit 4.

The reading unit 2 may be embodied using one or more of optical imaging apparatuses such as a stepper, a scanner, a diffractometer, an electron microscope, an optical microscope, an X-ray machine, etc., or other suitable positioning equipment, overlay error measuring equipment, etc.

The error calculating unit 3 is connected to the reading unit 2, and may include, but not limited to, one or more of a single core processor, a multi-core processor, a dual-core mobile processor, a microprocessor, a microcontroller, a digital signal processor (DSP), a field-programmable gate array (FPGA), an application specific integrated circuit (ASIC), a radio-frequency integrated circuit (RFIC), etc. The error calculating unit 3 may execute a software application to perform operations as described below.

The temperature controlling unit 4 is connected to the error calculating unit 3, and incudes at least one temperature controller 41 and a controlling component 42 that is connected to the error calculating unit 3 and the at least one temperature controller 41. In the embodiment of FIG. 1, three temperature controllers 41 are present, and the controlling component 42 is connected to each of the three temperature controllers 41.

In use, each of the three temperature controllers 41 may be embodied using a heat source such as a heat exchanger, a joule heating element, an infrared heater, an ultraviolet heater, a laser heater, etc., and/or a cooling source such as a chiller, a thermoelectric cooling chip, etc. The controlling component 42 may be embodied using a microcontroller or other suitable processing components that execute a software program to control operations of each of the three temperature controllers 41, and to perform operations as described below.

In use, the system 10 is to be used on a semiconductor substrate for compensating a manufacturing error of the semiconductor substrate so as to ensure accuracy of a subsequent overlay process.

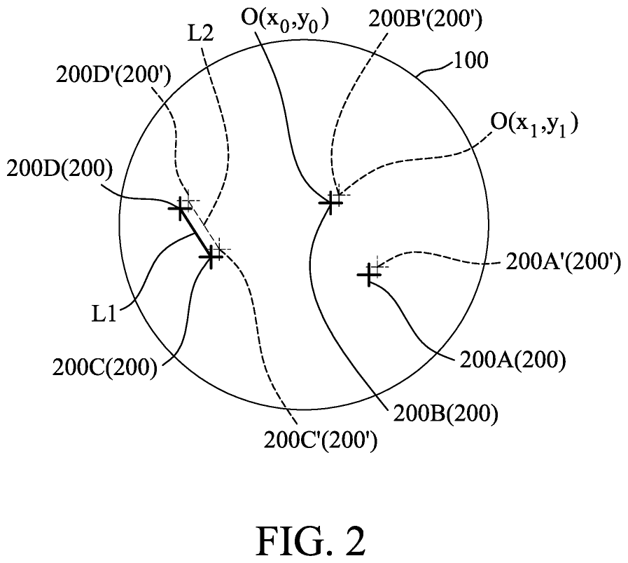

FIG. 2 illustrates an exemplary substrate 100 according to one embodiment of the disclosure. In embodiments, the substrate 100 has an alignment symbol 200 thereon. It is noted that the alignment symbol 200 may be formed on the substrate 100 using a first patterning process, which may be a photolithographic process, an etching process, etc. In embodiments, the substrate 100 may be formed using a glass material, a semiconductor material, a dielectric material, a metal material, etc.

The reading unit 2 is configured to capture an image of the substrate 100 that contains the alignment symbol 200, and to generate a reading signal associated with the alignment symbol 200. In embodiments, the reading signal may include the image and/or a set of coordinates indicating a location of the alignment symbol 200 on the substrate 100. The reading unit 2 is then configured to transmit the reading signal to the error calculating unit 3 for performing subsequent processes.

In response to receipt of the reading signal, the error calculating unit 3 is configured to determine a difference between the location of the alignment symbol 200 (based on the reading signal) and a location of a reference alignment symbol 200′, which may be deemed as an expected location of the alignment symbol 200.

In embodiments, the image of the substrate 100 may also include the reference alignment symbol 200′, and the location of the reference alignment symbol 200′ may be indicated by the image of the substrate 100. The reference alignment symbol 200′ may be formed on the substrate 100 in a second patterning process, which is performed immediately prior to or following the first patterning process. In some embodiments, an image of another substrate 100 having the reference alignment symbol 200′ may be pre-stored in the error calculating unit 3 or may be obtained by the reading unit 2 and transmitted to the error calculating unit 3. In some embodiments, a set of coordinates indicating the location of the reference alignment symbol 200′ may be pre-stored in the error calculating unit 3 or may be obtained by the reading unit 2 and transmitted to the error calculating unit 3.

Accordingly, the error calculating unit 3 may be configured to determine the difference using the two images respectively containing the alignment symbol 200 and the reference alignment symbol 200′ by overlaying the images and to determine a displacement of the alignment symbol 200 with respect to the reference alignment symbol 200′, or by comparing the two sets of coordinates respectively indicating the locations of the alignment symbol 200 and the reference alignment symbol 200′ (e.g., performing subtraction). Then, the error calculating unit 3 is configured to generate and output a difference signal indicating the difference. The difference signal may be in the form of a vector indicating the displacement (which may be deemed as a manufacturing error, since the location of the reference alignment symbol 200′ is the location at which the alignment symbol 200 is expected to be) or a set of coordinates that is a result of the subtraction. It is noted that a deviation of a current location from the expected location of the alignment symbol 200 may be caused by the manufacturing error in the semiconductor process.

The error calculating unit 3 is then configured to transmit the difference signal to the controlling component 42.

In response to receipt of the difference signal, the controlling component 42 generates at least one temperature controlling signal, and transmits the at least one temperature controlling signal to the at least one temperature controller 41.

Specifically, in the embodiments where a single temperature controller 41 is present, the temperature controller 41 is to be disposed near the substrate 100, and is configured to control a temperature of an affecting part of the substrate 100 (a temperature of an area of the affecting part may be predetermined based on an electrical power consumed by the temperature controller 41). In some cases, the alignment symbol 200 may be located within or adjacent to the affecting part.

The controlling component 42 may execute the software application to calculate a temperature controlling signal for the temperature controller 41 based on at least the difference signal. In some embodiments, the controlling component 42 calculates the temperature controlling signal based on the difference signal, a current temperature of the affecting part of the substrate 100 and a location of the temperature controller 41 with respect to the substrate 100. The temperature controlling signal indicates an adjusted temperature for the temperature controller 41, in order to control one of the temperature of the affecting part of the substrate 100, and a temperature of an affecting part of another substrate of following batches at the same stage of the semiconductor process, thereby adjusting the location of the alignment symbol 200.

In the embodiments where multiple temperature controllers 41 are present, each of the temperature controllers 41 may be disposed on a different affecting part of the substrate 100 and may be individually controlled by the controlling component 42 for independent temperature control of the affecting part. It is noted that in different embodiments, each of the temperature controllers 41 may be disposed near a top surface of the substrate 100 (illustrated in FIG. 2) or near a bottom surface of the substrate 100 opposite to the top surface.

In embodiments where a substrate 100 with a larger size and a large number of temperature controllers 41 is employed, the temperature controllers 41 may be arranged in specific manners such as concentric circles or a grid.

In embodiments, after a process is implemented on one substrate 100 to form the alignment symbol 200 thereon, the system 10 may be used to determine whether the alignment symbol 200 is formed on an expected location, and if not, determine how to adjust the temperature(s) of the temperature controller(s) 41 in order to ensure that the alignment symbol 200 is formed on an expected location of a substrate of the following batches at the same stage of the semiconductor process.

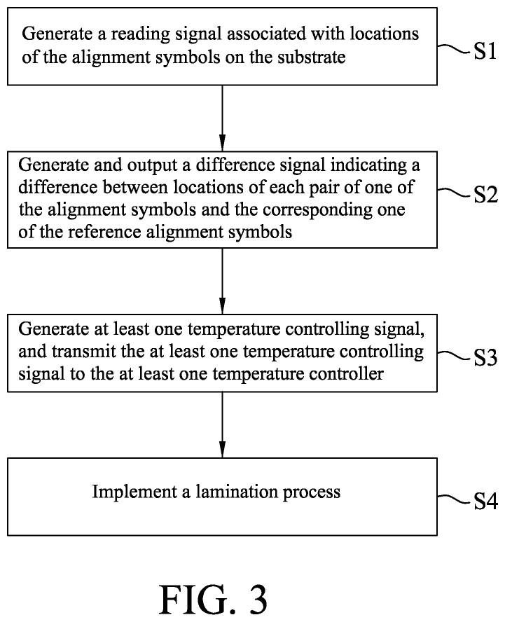

FIG. 3 is a flow chart illustrating steps of a method for compensating a manufacturing error in a semiconductor process using temperature control according to one embodiment of the disclosure. In some embodiments, the method is implemented using the system 10 as shown in FIG. 1 and is used on the substrate 100 as shown in FIG. 2.

In the example of FIG. 2, four alignment symbols 200 (being in the form of a solid cross and respectively labeled as 200A, 200B, 200C and 200D) and four reference alignment symbols 200′ (being in the form of a dashed cross and respectively labeled as 200A′, 200B′, 200C′ and 200D′) which correspond with the four alignment symbols 200, respectively, are present on the substrate 100. The alignment symbols 200 and the reference alignment symbols 200′ are formed on the substrate 100 using two patterning processes, respectively. As such, the image of FIG. 2 may be a result of an image of the substrate 100 containing the alignment symbols 200 and the reference alignment symbols 200′.

In the method, it is intended to determine whether each of the alignment symbols 200 and the corresponding one of the reference alignment symbols 200′ are aligned with each other. The three temperature controllers 41 are located near different parts of the substrate 100.

In step S1, the reading unit 2 is configured to generate a reading signal associated with locations of the alignment symbols 200 on the substrate 100. Specifically, the reading unit 2 may obtain an image of the substrate 100 to determine a location of each of the alignment symbols 200. Alternatively, the reading unit 2 may determine a set of coordinates of each of the alignment symbols 200. Then, the reading unit 2 generates the reading signal to include the location of each of the alignment symbols 200 and/or the set of coordinates of each of the alignment symbols 200. Afterwards, the reading unit 2 transmits the reading signal to the error calculating unit 3.

Then, in step S2, the error calculating unit 3 generates and outputs a difference signal indicating a difference between locations of each pair of one of the alignment symbols 200 and the corresponding one of the reference alignment symbols 200′.

Specifically, in the embodiments where an image of the substrate 100 as shown in FIG. 2 is used, the error calculating unit 3 may determine the displacement between each of the alignment symbols 200 and the corresponding one of the reference alignment symbols 200′. In other embodiments, the error calculating unit 3 may be configured to determine the difference using the two images respectively containing an alignment symbol 200 and a reference alignment symbol 200′ by overlaying the images and to determine a displacement of the alignment symbol 200 with respect to the reference alignment symbol 200′, or by comparing the two sets of coordinates respectively indicating the locations of the alignment symbol 200 and the reference alignment symbol 200′ (e.g., performing a subtraction). It is noted that in different cases, the image of the reference alignment symbol(s) 200′ may be pre-stored in the error calculating unit 3, or may be obtained by the reading unit 2.

Then, the error calculating unit 3 is configured to generate a difference signal indicating the difference. The difference signal may be, for each pair of one of the alignment symbols 200 and the corresponding one of the reference alignment symbols 200′, in the form of a vector indicating the displacement (which may be deemed as a manufacturing error, since the location of the reference alignment symbol 200′ is the location at which the alignment symbol 200 is expected to be) or a set of coordinates that is a result of the subtraction. Then, the error calculating unit 3 transmits the difference signal to the controlling component 42.

In response to receipt of the difference signal, in step S3, the controlling component 42 generates at least one temperature controlling signal, and transmits the at least one temperature controlling signal to the at least one temperature controller 41. In the case where the system 10 of FIG. 1 is used, three temperature controllers 41 are present, and the controlling component 42 generates three temperature controlling signals each for controlling the operation of a corresponding one of the temperature controllers 41, so as to ensure that the temperature controllers 41 respectively control the temperatures of affecting parts of the substrate 100.

In some embodiments, controlling operations of the temperature controllers 41 may be performed with respect to the substrate 100. For example, the method may be implemented during a semiconductor process, right after the process of forming the alignment symbols 200 is completed. At this stage, the substrate 100 may include incomplete semiconductor devices thereon, and after generating the temperature controlling signals, the controlling component 42 may directly transmit the temperature controlling signals to the temperature controllers 41 disposed near the substrate 100.

As such, controlling the operations of the temperature controllers 41 may directly cause different affecting parts of the substrate 100 to expand or shrink, therefore adjusting the locations of the alignment symbols 200 on the substrate 100. In this way, the manufacturing error, i.e., deviation of the alignment symbols 200 from their expected locations, may be compensated. This prepares the substrate 100 for subsequent processes in which, for example, another substrate may be formed on a top surface of the substrate 100. The temperature controlling signals may also be stored and used in subsequent processes for adjusting locations of the alignment symbols 200 on other substrates.

Alternatively, step S3 of the method may be implemented after the semiconductor process is completed. As such, after generating the temperature controlling signals, the controlling component 42 stores the temperature controlling signals so as to use in other substrates of a next batch in the same semiconductor process, for adjusting locations of the alignment symbols 200 on the other substrates.

In some embodiments where the method is implemented during a semiconductor process, the operation of step S3 may be done in a manner as described below. Referring to FIG. 2, the reading signal obtained by the reading unit 2 in step S1 may be in the form of sets of coordinates. For example, the location of one of the alignment symbols 200B may be included in the reading signal as a set of coordinates (X₀, Y₀), indicating a location of a central point of the alignment symbol 200B (i.e., the intersection of the cross). Then in step S2, the error calculating unit 3 generates the difference signal by determining the difference between the set of coordinates (X₀, Y₀) associated with the alignment symbol 200B and a set of coordinates (X₁, Y₁) associated with the corresponding one of the reference alignment symbols 200B′. It is then determined that the alignment symbol 200B deviates from the expected location on the substrate 100, and should be shifted toward the location of the reference alignment symbol 200B′.

In embodiments where one of the temperature controllers 41 is disposed to affect an affecting part of the substrate 100 that is on the left of the alignment symbol 200B or that is lower than the alignment symbol 200B, in step S3, the controlling component 42 may generate the temperature controlling signal to control the temperature controller 41 to heat the affecting part. As such, the affecting part of the substrate may expand as a result of the increased temperature, pushing the alignment symbol 200B toward the location of the reference alignment symbol 200B′. As a result, a manufacturing error associated with the alignment symbol 200B may be compensated.

In some embodiments where the method is implemented during a semiconductor process, the operation of step S3 may be done in a manner as described below. Referring to FIG. 2, the reading signal obtained by the reading unit 2 in step S1 may be in the form of sets of coordinates or images. Then, in step S2, the error calculating unit 3 generates the difference signal by determining a length of a segment L1 interconnecting the central points of two nearby alignment symbols (e.g., 200C and 200D). Then, the error calculating unit 3 compares the length of the segment L1 and a length of another segment L2 that interconnects the central points of two corresponding reference alignment symbols (e.g., 200C′ and 200D′).

In the case where the length of the segment L1 is smaller than the length of the segment L2, and one of the temperature controllers 41 is disposed to affect an affecting part of the substrate 100 between the alignment symbols 200C and 200D, in step S3, the controlling component 42 may generate the temperature controlling signal to control the temperature controller 41 to heat the affecting part. As such, the affecting part of the substrate 100 may expand as a result of an increased temperature, pushing the alignment symbols 200C and 200D away from each other. As such, a difference between the lengths of the segments L1 and L2 may be reduced.

On the other hand, in the case where the length of the segment L1 is larger than the length of the segment L2, in step S3, the controlling component 42 may generate the temperature controlling signal to control the temperature controller 41 to chill the affecting part. As such, the affecting part of the substrate 100 may shrink as a result of a decreased temperature, pulling the alignment symbols 200C and 200D toward each other. As such, a difference between the lengths of the segments L1 and L2 may be reduced.

In some embodiments where the temperature controllers 41 are disposed in a manner of concentric circles, after a difference signal is received, the controlling component 42 may generate the temperature controlling signal to control the temperature controllers 41 to adjust temperatures in order to perform a more complicated overlay control.

It is noted that in embodiments, when it is determined that the manufacturing error (e.g., a distance between locations of an alignment symbol 200 and a corresponding reference alignment symbol 200′) is smaller than a predetermined threshold, the subsequent overlay control may be unnecessary. That is to say, depending on different semiconductor processes, a relatively low degree of manufacturing error may be tolerable without having to take measures to reduce the manufacturing error. In some embodiments, the operations of step S3 cause the manufacturing error to reduce to below the predetermined threshold, and the predetermined threshold may be set in advance based on different needs and requirements.

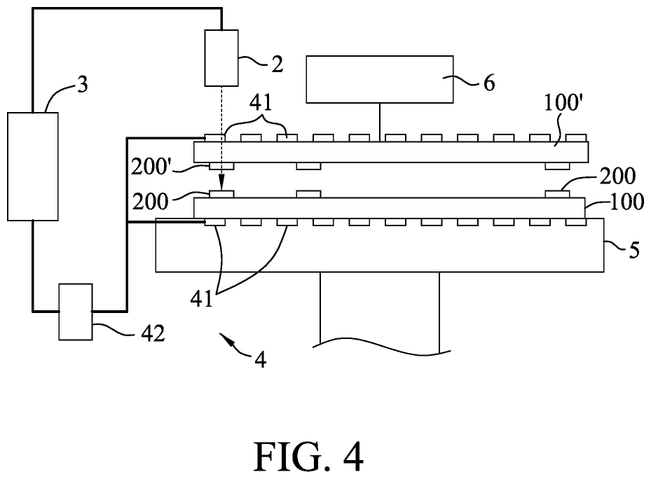

FIG. 4 is a schematic diagram illustrating a system 11 for overlay control in a semiconductor process according to one embodiment of the disclosure. In the embodiment of FIG. 4, the system 11 further includes a securing unit 5 that is for securing the substrate 100 after temperature control related to step S3 is performed on the substrate 100 (that is, after the controlling of the temperature of the affecting part of the substrate 100 is implemented, affecting parts of the substrate 100 are deformed as a result). In some embodiments, the securing unit 5 may be used in the cases where the method for compensating a manufacturing error is implemented during the semiconductor process. In the embodiment of FIG. 4, the securing unit 5 may be embodied using a vacuum holder that is configured to secure the substrate 100. In the cases where the securing unit 5 is embodied using the vacuum holder, the temperature controllers 41 may be disposed in the securing unit 5.

In the embodiment of FIG. 4, two substrates 100 and 100′ are to be bonded as two layers, in a lamination process. Each of the substrates 100 and 100′ may be embodied using a wafer, a die or a chip. The substrate 100 includes a plurality of alignment symbols 200, and the substrate 100′ includes a plurality of reference alignment symbols 200′ corresponding with the alignment symbols 200, respectively. In FIG. 4, three alignment symbols 200 and three reference alignment symbols 200′ are present. The substrate 100 is secured by the securing unit 5, and therefore the process of compensating a manufacturing error may be done with respect to the substrate 100.

Prior to the lamination process, the method of FIG. 3 may be implemented, in which the reading unit 2 generates the reading signal, and the error calculating unit 3 generates a difference signal based on the reading signal. As such, it may be determined prior to implementing the lamination process, whether the substrates 100 and 100′ are suitable to be bonded (e.g., whether an overlay error between each pair of one of the alignment symbols 200 and a corresponding one of the reference alignment symbols 200′ is tolerable). In the case where it is determined that temperature control is necessary, the controlling component 42 may generate the temperature controlling signals to control the temperature controllers 41 to control temperatures of the affecting parts in order to adjust locations of the alignment symbols 200. Afterwards, the method may be continued to implement the lamination process with the substrates 100 and 100′, so as to bond the substrates 100 and 100′ together with reduced overlay errors. It is noted that in some embodiments, the temperature control may be done with respect to one or both of the substrates 100 and 100′. For example, in some cases, the controlling component 42 may generate the temperature controlling signals to control the temperature controllers 41 disposed near the substrate 100′ to control temperatures of one or more affecting parts of the substrate 100′ in order to adjust locations of the reference alignment symbols 200′. Alternatively, the controlling component 42 may generate the temperature controlling signals to control the temperature controllers 41 to control temperatures of the affecting parts of both the substrates 100 and 100′ in order to adjust locations of the alignment symbols 200 and locations of the reference alignment symbols 200′. After the temperature control of step S3 is implemented, the lamination process is implemented in step S4 to bond the substrates 100 and 100′ together. In use, the system 10 may further include a lamination unit 6 for implementing the lamination process. The lamination unit 6 may be embodied using a wafer bonding machine or other suitable equipment.

In some embodiments, after the temperature control, a securing layer may be formed on the substrate 100 in order to hold the substrate 100 in a deformed state (i.e., being deformed due to the increased temperature or the decreased temperature).

The securing layer may be formed, after the temperature control is performed on the substrate 100, on the substrate 100 by applying an adhesive material thereon, and subsequently implementing a curing process (e.g., heat curing or light curing) on the adhesive material, in order to secure the substrate 100 in the deformed state.

To sum up, embodiments of the disclosure provides a method for compensating a manufacturing error in a semiconductor process using temperature control. In the method, a system determines whether a temperature control is needed by calculating a difference between a location of an alignment symbol on a substrate and a location of a reference alignment symbol. When it is determined that the temperature control is needed, a temperature controller is controlled by a temperature controlling signal to heat or chill an affecting part of the substrate, in order to cause the affecting part to deform. As such, the manufacturing error during the semiconductor process may be reduced. The temperature controlling signal used for controlling the temperature controller may also be stored for a next batch of substrates in the same semiconductor process.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for compensating a manufacturing error in a semiconductor process, the method being implemented using a system that includes at least one temperature controller, the method comprising:
generating a reading signal associated with a location of an alignment symbol on a substrate;
generating a difference signal based on the reading signal, the difference signal indicating a difference between the location of the alignment symbol and a location of a reference alignment symbol that corresponds with the alignment symbol, wherein the reference alignment symbol is on another substrate; and
generating a temperature controlling signal based on the difference signal, the temperature controlling signal controlling operation of the temperature controller in order to control one of a temperature of an affecting part of the substrate, a temperature of an affecting part of the another substrate and a combination thereof; and
after controlling the one of a temperature of an affecting part of the substrate, a temperature of an affecting part of the another substrate and a combination thereof, performing a lamination process to bond the substrate and the another substrate together.

2. The method as claimed in claim 1, wherein the reading signal includes one of an image of the substrate and a set of coordinates indicating a location of the alignment symbol on the substrate.

3. The method as claimed in claim 1, the system including a plurality of temperature controllers that are arranged in concentric circles, wherein the temperature controlling signal includes a plurality of temperature controlling signals for controlling operations of the temperature controllers.

4. The method as claimed in claim 1, wherein the alignment symbol is located adjacent to the affecting part of the substrate.

5. The method as claimed in claim 1, wherein the substrate is formed using one of a glass material, a semiconductor material, a dielectric material, and a metal material.

6. The method as claimed in claim 1, wherein in controlling operation of the temperature controller, one of the temperature of the affecting part of the substrate, the temperature of the affecting part of the another substrate and the combination thereof is adjusted, so as to cause one of the affecting part of the substrate, the affecting part of the another substrate and a combination thereof to deform for compensating the manufacturing error.

7. The method as claimed in claim 1, further comprising storing the temperature controlling signal for processing a substrate of a next batch in the semiconductor process.

8. The method as claimed in claim 1, wherein the temperature controlling signal controls the temperature of the affecting part of the substrate, the method further comprising, after controlling the temperature of the affecting part of the substrate, forming a securing layer on the substrate in order to hold the substrate in a deformed state.

9. A system for compensating a manufacturing error in a semiconductor process, comprising:
a reading unit that generates a reading signal associated with an alignment symbol formed on a substrate;
an error calculating unit that, in response to receipt of the reading signal, determines a difference between a location of the alignment symbol and a location of a reference alignment symbol formed on another substrate, and generates a difference signal based on the reading signal, the difference signal indicating the difference; and
a temperature controlling unit that, in response to receipt of the difference signal, generates at least one temperature controlling signal based on the difference signal, the temperature controlling signal controlling one of a temperature of an affecting part of the substrate, a temperature of an affecting part of the another substrate and a combination thereof; and
a lamination unit that is configured to, after controlling the one of a temperature of an affecting part of the substrate, a temperature of an affecting part of the another substrate and a combination thereof, perform a lamination process to bond the substrate and the another substrate together.

10. The system as claimed in claim 9, wherein:
the temperature controlling unit includes a temperature controller disposed near the substrate and a controlling component connected to the temperature controller; and
the controlling component, in response to the receipt of the difference signal, generates the at least one temperature controlling signal and controls operation of the temperature controller for controlling the one of the temperature of the affecting part of the substrate, and the temperature of the affecting part of the another substrate of the next batch in the semiconductor process.

11. The system as claimed in claim 9, wherein the reading signal includes one of an image of the substrate and a set of coordinates indicating a location of the alignment symbol on the substrate.

12. The system as claimed in claim 9, further comprising a securing unit, wherein:
the temperature controlling signal controls the temperature of the affecting part of the substrate; and
the securing unit is for securing the substrate after the controlling of the temperature of the affecting part of the substrate is implemented.

13. The system as claimed in claim 12, wherein the securing unit is a vacuum holder, and temperature controllers are disposed in the securing unit.

14. The system as claimed in claim 9, wherein in controlling operation of the temperature controlling unit, the temperature of the affecting part of the substrate is adjusted, so as to cause the affecting part of the substrate to deform for compensating the manufacturing error.

15. The system as claimed in claim 9, wherein the temperature controlling unit further stores the temperature controlling signal for processing a substrate of a next batch in the semiconductor process.
